(19) United States
(12) Patent Application Publication
(10) Pub. No.: US 2002/0024364 A1
(43) Pub. Date: Feb. 28, 2002

(54) Frequency synthesizer having shortened lock-up time

(75) Inventors: Kazuharu Aoki, Fukushima-ken (JP); Shoichi Asano, Fukushima-ken (JP)

Correspondence Address: Brinks Hofer Gilson & Lione, P.O. Box 10395, Chicago, IL, 60610, US

(73) Assignee: Alps Electric Co., Ltd.

(21) Appl. No.: 09/934,494

(22) Filed: Aug. 22, 2001

(30) Foreign Application Priority Data
Aug. 31, 2000 (JP) 2000-268409

(51) Int. Cl. H03B 21/00

(52) U.S. Cl. 327/105

(57) ABSTRACT

In order to shorten the lock-up time, a frequency synthesizer includes a first voltage-controlled oscillator which is controlled by a first PLL circuit and which outputs a first oscillation signal; a second voltage-controlled oscillator which is controlled by a second PLL circuit and which outputs a second oscillation signal; and a mixer which outputs a signal of addition or subtraction between the first oscillation signal and the second oscillation signal, wherein the first voltage-controlled oscillator is made to oscillate at a spacing of a first step frequency, the second voltage-controlled oscillator is made to oscillate at a spacing of a second step frequency which is lower than the first step frequency, and a reference frequency of the first PLL circuit is higher than a reference frequency of the second PLL circuit.

### BACKGROUND OF THE INVENTION

1. Field of the Invention

The present invention relates to a frequency synthesizer which is suitable for use in local oscillators, such as cellular telephones.

2. Description of the Related Art

A conventional frequency synthesizer, as shown in FIG. 4, comprises a voltage-controlled oscillator 51, a reference oscillator 52, and a PLL (phase-locked loop) circuit 53, etc. An oscillation signal output from the voltage-controlled oscillator 51 is input to a mixer of a transmission circuit or a receiving circuit in a cellular telephone (not shown). At the same time, the oscillation signal is frequency-divided by a fixed frequency divider 53a of the PLL circuit 53 and is input to a programmable frequency divider 53b.

Data D for setting the oscillation frequency of the voltage-controlled oscillator 51 is input to the programmable frequency divider 53b. Then, the oscillation signal input to the programmable frequency divider 53b is further frequency-divided in accordance with this data and is input as a comparison frequency signal to a phase comparator 53c.

Also, an oscillation signal output from the reference oscillator 52 is frequency-divided by a fixed frequency divider 54 and is input as a reference frequency signal to the phase comparator 53c. In the phase comparator 53c, the phase of the reference frequency signal is compared with the phase of the comparison frequency signal, and an error signal based on the phase difference is output. The error signal is smoothed by a loop filter 53d and is applied as a control voltage to a varactor diode (not shown) of the voltage-controlled oscillator 51. As a result, the voltage-controlled oscillator 51 is controlled so as to oscillate at a frequency set by the data D.

A frequency synthesizer such as that described above is used as, for example, a local oscillator of a cellular telephone. In the cellular telephone, since there are 833 speech channels and the channel spacing is 30 KHz, the voltage-controlled oscillator 51, as shown in FIG. 5, is controlled so as to oscillate at a spacing of 30 KHz in a range of 954.39 MHz to 979.35 MHz. For this reason, the frequency of the reference frequency signal input to the phase comparator 53c is 30 KHz divided by an integer, being 30 KHz at a maximum.

It is preferable that the changing of a speech channel (therefore, the changing of the oscillation frequency of the voltage-controlled oscillator 51) be performed quickly. However, in the conventional frequency synthesizer described above, the ratio of the reference frequency to the oscillation frequency is large, thereby presenting the problem in that the time until the changing of the oscillation frequency is completed (this is called a “lock-up time”) is increased. Furthermore, the ratio of the range of the oscillation frequency to the reference frequency 24.96 MHz (=979.35 MHz—954.39 MHz) being large causes the lock-up time to be increased.

### SUMMARY OF THE INVENTION

Accordingly, the frequency synthesizer of the present invention aims to shorten the lock-up time.

To this end, according to the present invention, there is provided a frequency synthesizer comprising: a first voltage-controlled oscillator which is controlled by a first PLL circuit and which outputs a first oscillation signal; a second voltage-controlled oscillator which is controlled by a second PLL circuit and which outputs a second oscillation signal; and a mixer which outputs a signal of addition or subtraction between the frequency of the first oscillation signal and the frequency of the second oscillation signal, wherein the first voltage-controlled oscillator is made to oscillate at a spacing of a first step frequency, the second voltage-controlled oscillator is made to oscillate at a spacing of a second step frequency which is lower than the first step frequency, and a reference frequency of the first PLL circuit is higher than a reference frequency of the second PLL circuit. With this construction, it is possible to shorten the lock-up time.

The reference frequency of the first PLL circuit is preferably the first step frequency, and the reference frequency of the second PLL circuit is preferably the second step frequency. Therefore, it is possible to shorten the lock-up time even more.

The second voltage-controlled oscillator is preferably made to oscillate at the first step frequency. Therefore, it is possible to easily extract a signal of the frequency of the sum of the frequency of the first oscillation signal and the frequency of the second oscillation signal.

The mixer may comprise a first mixer and a second mixer. A first phase shifter which generates an oscillation signal whose phase differs by 90 degrees from the phase of the first oscillation signal, a second phase shifter which generates an oscillation signal whose phase differs by 90 degrees from the phase of the second oscillation signal, and an adder which adds together a signal output from the first mixer and a signal output from the second mixer may be provided. Oscillation signals whose phases lead by 90 degrees, which are output from the first and second phase shifters, may be input to the first mixer, and an oscillation signal whose phase lags by 90 degrees may be input to the second mixer. Therefore, it is possible to easily extract a signal of the frequency of the sum thereof.

The above and further objects, aspects and novel features of the invention will become more fully apparent from the following detailed description when read in conjunction with the accompanying drawings.

### BRIEF DESCRIPTION OF THE DRAWINGS

FIG. 1 is a circuit diagram showing the construction of a frequency synthesizer of the present invention;

FIG. 2 is an illustration of an oscillation frequency of a voltage-controlled oscillator in the frequency synthesizer of the present invention;

FIG. 3 is a circuit diagram showing another construction of the frequency synthesizer of the present invention;

FIG. 4 is a circuit diagram showing the construction of a conventional frequency synthesizer; and

FIG. 5 is an illustration of an oscillation frequency of a voltage-controlled oscillator in the conventional frequency synthesizer.

### DESCRIPTION OF THE PREFERRED EMBODIMENT

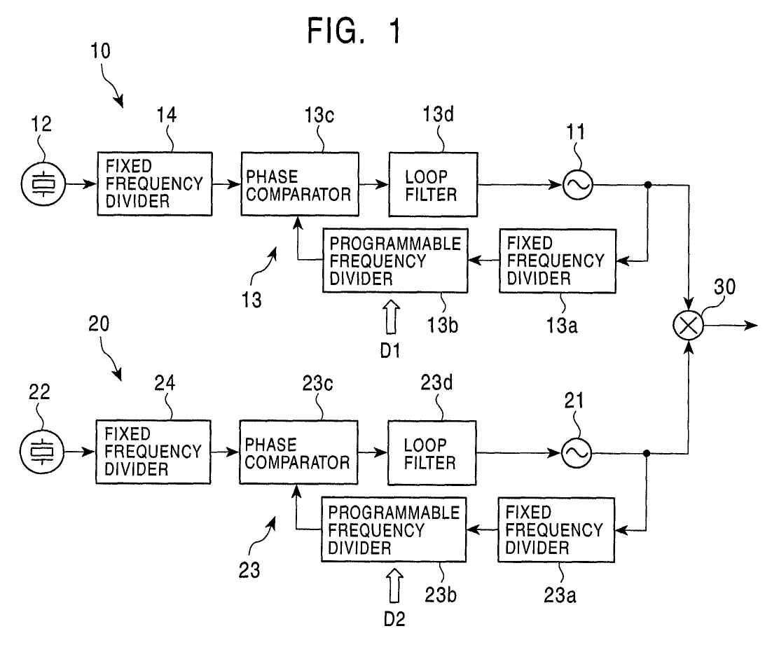

A frequency synthesizer of the present invention will now be described below with reference to the attached drawings. Referring to FIG. 1, a first frequency synthesizer 10 comprises a first voltage-controlled oscillator 11, a first reference oscillator 12, and a first PLL circuit 13, etc. A first oscillation signal output from the first voltage-controlled oscillator 11 is frequency-divided by a fixed frequency divider 13a of the first PLL circuit 13 and is input to a programmable frequency divider 13b.

Data D1 for setting the oscillation frequency of the first voltage-controlled oscillator 11 is input to the programmable frequency divider 13b. Then, the oscillation signal input to the programmable frequency divider 13b is further frequency-divided in accordance with the data D1 and is input as a first comparison frequency signal to a phase comparator 13c.

Furthermore, an oscillation signal output from the first reference oscillator 12 is frequency-divided by a fixed frequency divider 14 and is input as a first reference frequency signal to the phase comparator 13c. In the phase comparator 13c, the phase of the first reference frequency signal is compared with the phase of the first comparison frequency signal, and an error signal based on the phase difference is output. The error signal is smoothed by a loop filter 13d and is applied as a first control voltage to a varactor diode (not shown) of the voltage-controlled oscillator 11. As a result, the voltage-controlled oscillator 11 is controlled so as to oscillate at a frequency set by the data D1.

Meanwhile, a second frequency synthesizer 20 comprises a second voltage-controlled oscillator 21, a second reference oscillator 22, a second PLL circuit 23, etc. A second oscillation signal output from the second voltage-controlled oscillator 21 is frequency-divided by a fixed frequency divider 23a of the second PLL circuit 23 and is input to a programmable frequency divider 23b. Data D2 for setting the oscillation frequency of the second voltage-controlled oscillator 21 is input to the programmable frequency divider 23b. Then, the oscillation signal input to the programmable frequency divider 23b is further frequency-divided in accordance with the data D2 and is input as a second comparison frequency signal to a phase comparator 23c.

Furthermore, an oscillation signal output from the second reference oscillator 22 is frequency-divided by a fixed frequency divider 24 and is input as a second reference frequency signal to the phase comparator 23c. In the phase comparator 23c, the phase of the second reference frequency signal is compared with the phase of the second comparison frequency signal, and an error signal based on the phase difference is output. The error signal is smoothed by a loop filter 23d and is applied as a second control voltage to a varactor diode (not shown) of the second voltage-controlled oscillator 21. As a result, the second voltage-controlled oscillator 21 is controlled so as to oscillate at a frequency set by the data D2.

The first oscillation signal output from the first voltage-controlled oscillator 11 and the second oscillation signal output from the second voltage-controlled oscillator 21 are input to a mixer 30. Therefore, a signal of a frequency of addition or subtraction between the frequency of the first oscillation signal and the frequency of the second oscillation signal is output from the mixer 30.

The fixed frequency dividers 13a, 14, 23a, and 24 in FIG. 1 are not necessarily required.

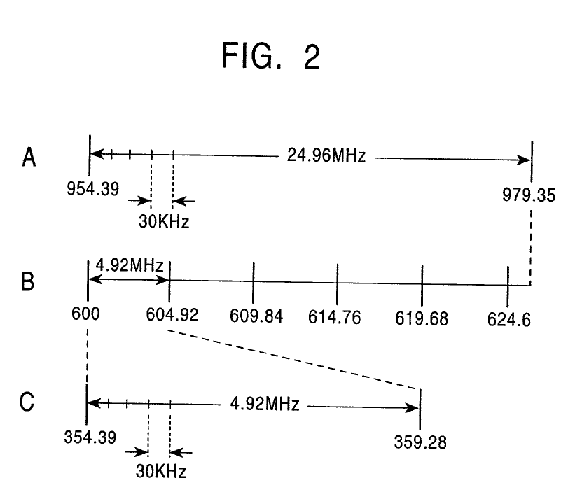

In a case where the frequency synthesizer having the above-described construction is used as a local oscillator of a cellular telephone, as shown in part A of FIG. 2, the frequency range of the necessary local oscillation signal is 954.39 MHz to 979.35 MHz, and within this range, the signal must be output at the spacing of a step frequency of 30 KHz.

Therefore, as shown in part B of FIG. 2, first, the first voltage-controlled oscillator 11 is controlled so as to oscillate at the spacing of a first step frequency of 4.92 MHz in a range of 600 MHz to 624.6 MHz.

Also, as shown in part C of FIG. 2, the second voltage-controlled oscillator 21 is controlled so as to oscillate at the spacing of a second step frequency of 30 KHz in a range of 354.39 MHz to 359.28 MHz.

Then, by inputting the first oscillation signal output from the first voltage-controlled oscillator 11 and the second oscillation signal output from the second voltage-controlled oscillator 21 to the mixer 30 and by extracting the signal of the frequency of the sum of each frequency from the mixer 30, it is possible to obtain a local oscillation signal at a spacing of a step frequency of 30 KHz within a frequency range of 954.39 MHz to 979.35 MHz.

Consequently, in the first frequency synthesizer 10, the ratio of the first reference frequency to the oscillation frequency of the first voltage-controlled oscillator 11 and the ratio of the first reference frequency to the oscillation frequency change range of the first voltage-controlled oscillator 11 are decreased, and the lock-up time is shortened.

In a similar manner, also in the second frequency synthesizer 20, the ratio of the second reference frequency to the oscillation frequency of the second voltage-controlled oscillator 21 and the ratio of the second reference frequency to the oscillation frequency change range of the second voltage-controlled oscillator 21 are decreased, and the lock-up time is shortened.

Furthermore, in the first frequency synthesizer 10, the first reference frequency is made to match the first step frequency, and in the second frequency synthesizer 20, the second reference frequency is made to match the second step frequency. Therefore, it is possible to cause each frequency synthesizer to operate at the best lock-up time.

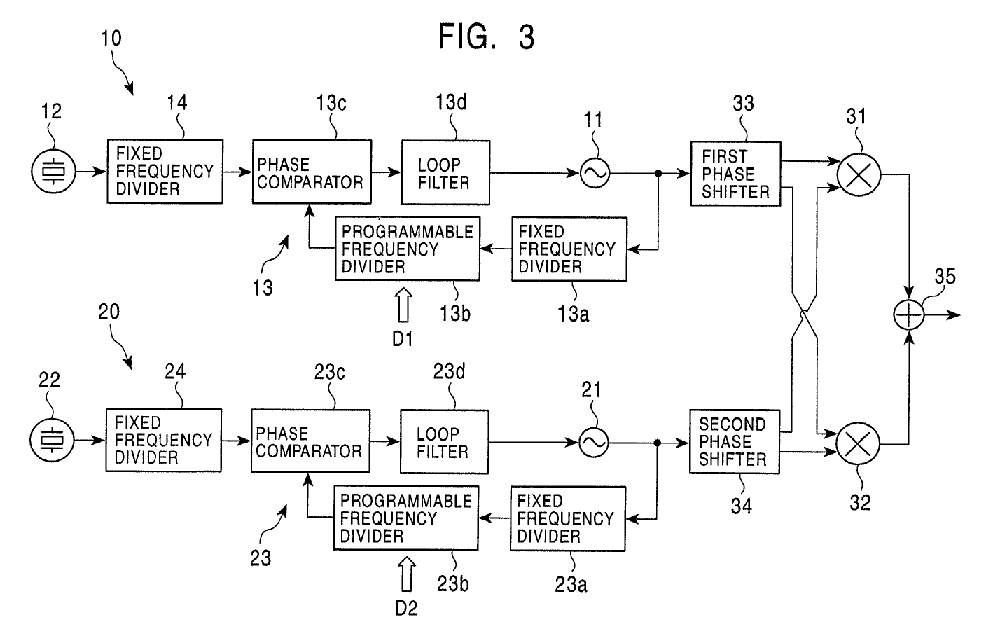

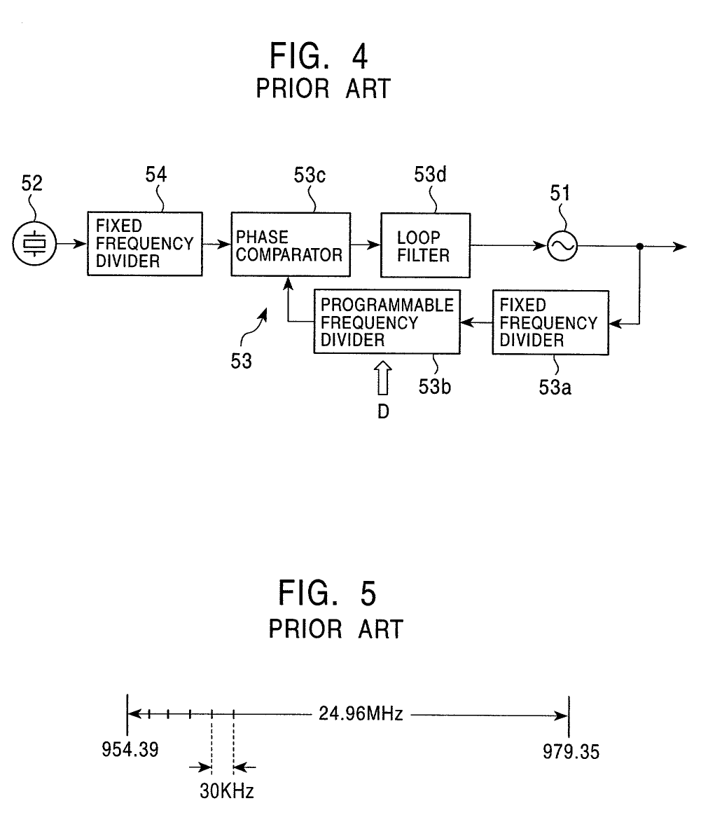

FIG. 3 shows a modification of the frequency synthesizer shown in FIG. 1. For the mixer 30, two mixers of a first mixer 31 and a second mixer 32 are used. Also, a first phase shifter 33 is provided on the output side of the first voltage-controlled oscillator 11, and a second phase shifter 34 is provided on the output side of the second voltage-controlled oscillator 21. Furthermore, an adder 35 is provided on the output side of the first and second mixers 31 and 32. The remaining construction is the same as that of FIG. 1.

Then, the first oscillation signal output from the first voltage-controlled oscillator 11 is input to the first phase shifter 33. The first phase shifter 33 outputs an oscillation signal which is in phase (0 degree) with the first oscillation signal and an oscillation signal which is 90 degrees out of phase from the first oscillation signal. The in-phase oscillation signal is input to the first mixer 31, and the oscillation signal which is 90 degrees out of phase is input to the second mixer 32.

Furthermore, the second oscillation signal output from the second voltage-controlled oscillator 21 is input to the second phase shifter 34. The second phase shifter 34 also outputs an oscillation signal which is in phase (0 degree) with the second oscillation signal and an oscillation signal which is 90 degrees out of phase from the second oscillation signal. The in-phase oscillation signal is input to the first mixer 31, and the oscillation signal which is 90 degrees out of phase is input to the second mixer 32.

Then, the signal output from the first mixer 31 and the signal output from the second mixer 32 are added together by the adder 35.

Here, if the angular frequency of the first oscillation signal is denoted as ω₁ and the oscillation signal which is in phase with that signal is denoted as sin ω₁t, the oscillation signal which is 90 degrees out of phase becomes cos ω₁t. Also, if the angular frequency of the second oscillation signal is denoted as ω₂ and the oscillation signal which is in phase with that signal is denoted as sin ω₂t, the oscillation signal which is 90 degrees out of phase becomes cos ω₂t.

Therefore, “sin ω₁t+sin ω₂t” is input to the first mixer 31, and “cos ω₁t+ω₂t” is input to the second mixer 32. As a result, “cos (ω₁+ω₂)t−cos (ω₁−ω₂)t” is output from the first mixer 31, and “cos (ω₁+ω₂)t+cos (ω₁−ω₂)t” is output from the second mixer 32. Therefore, cos (ω₁−ω₂)t is cancelled by the adder 35 and cos (ω₁+ω₂)t is output.

In the manner described above, as a result of providing the mixers 31 and 32, the phase shifters 33 and 34, and the adder 35, it is possible to easily extract a signal of the frequency of the sum of each frequency of the first oscillation signal and the second oscillation signal.

Many different embodiments of the present invention may be constructed without departing from the spirit and scope of the present invention. It should be understood that the present invention is not limited to the specific embodiment described in this specification. To the contrary, the present invention is intended to cover various modifications and equivalent arrangements included within the spirit and scope of the invention as hereafter claimed. The scope of the following claims is to be accorded the broadest interpretation so as to encompass all such modifications, equivalent structures and functions.

What is claimed is:

1. A frequency synthesizer comprising:
a first voltage-controlled oscillator which is controlled by a first PLL circuit and which outputs a first oscillation signal;
a second voltage-controlled oscillator which is controlled by a second PLL circuit and which outputs a second oscillation signal; and
a mixer which outputs a signal of addition or subtraction between the frequency of said first oscillation signal and the frequency of said second oscillation signal,
wherein said first voltage-controlled oscillator is made to oscillate at a spacing of a first step frequency, said second voltage-controlled oscillator is made to oscillate at a spacing of a second step frequency which is lower than said first step frequency, and a reference frequency of said first PLL circuit is higher than a reference frequency of said second PLL circuit.

2. A frequency synthesizer according to claim 1, wherein the reference frequency of said first PLL circuit is said first step frequency, and the reference frequency of said second PLL circuit is said second step frequency.

3. A frequency synthesizer according to claim 1, wherein said second voltage-controlled oscillator is made to oscillate in a range of said first step frequency.

4. A frequency synthesizer according to claim 1, wherein said mixer comprises a first mixer and a second mixer, there is provided a first phase shifter which generates an oscillation signal whose phase differs by 90 degrees from the phase of said first oscillation signal, a second phase shifter which generates an oscillation signal whose phase differs by 90 degrees from the phase of said second oscillation signal, and an adder which adds together a signal output from said first mixer and a signal output from said second mixer, oscillation signals whose phases lead by 90 degrees, which are output from said first and second phase shifters, are input to said first mixer, and an oscillation signal whose phase lags by 90 degrees is input to said second mixer.
